(19) United States
(12) Patent Application Publication
(10) Pub. No.: US 2020/0178388 A1
(43) Pub. Date: Jun. 4, 2020

(54) FIBER COMPOSITE LAMINATE INCLUDING SELF-ASSEMBLED CONDUCTIVE PASTE AND METHOD OF MANUFACTURING SAME

(71) Applicant: KOREA INSTITUTE OF INDUSTRIAL TECHNOLOGY, Cheonan-si (KR)

(72) Inventors: Eui Sang YOO, Gunpo-si (KR); Hyun Kyung LEE, Suwon-si (KR); Eunjoo KIM, Seoul (KR); Jung Hun LEE, Seoul (KR); Soo Hyeon RHO, Seoul (KR); Dae Young LIM, Yongin-si (KR); Ju Hee SO, Seoul (KR)

(73) Assignee: KOREA INSTITUTE OF INDUSTRIAL TECHNOLOGY, Cheonan-si (KR)

(21) Appl. No.: 16/699,286

(22) Filed: Nov. 29, 2019

(30) Foreign Application Priority Data
Nov. 30, 2018 (KR) 10-2018-0151959
Nov. 15, 2019 (KR) 10-2019-0146917

(51) Int. Cl. H05K 1/03; C08J 5/24; B32B 7/12; B32B 27/12; H05K 1/02; H05K 3/46

(52) U.S. Cl. CPC H05K 1/0313; C08J 5/24; B32B 7/12; B32B 27/12; H05K 1/0277; H05K 3/4644; H05K 2201/0278; C08J 2361/06; C08J 2467/00; B32B 2457/00; B32B 2307/202; H05K 2203/1105; C08J 2335/02

(57) ABSTRACT

Disclosed are a fiber composite laminate including a self-assembled conductive paste and a method of manufacturing the same. The fiber composite laminate includes a fiber-based circuit unit including a fiber substrate and a circuit electrode positioned on the fiber substrate, a composite binder unit positioned on the fiber-based circuit unit, and a connection unit including a connection electrode positioned on the composite binder unit and a flexible substrate positioned on the composite binder unit and the connection electrode. The fiber composite laminate can thus be applied to wearable devices having increased conductivity and durability of joints thereof, a minimized foreign-body sensation, and an improved wearing sensation. Moreover, productivity can be increased owing to a simple manufacturing process, and mass production becomes possible.

### CROSS REFERENCE TO RELATED APPLICATION

The present application claims priority based on Korean Patent Application Nos. 10-2018-0151959, filed on Nov. 30, 2018 and 10-2019-0146917, filed on Nov. 15, 2019, the entire contents of which are incorporated herein for all purposes by these references.

### BACKGROUND OF THE INVENTION

### 1. Technical Field

The present invention relates to a fiber composite laminate and a method of manufacturing the same, and more particularly to a fiber composite laminate, which includes a self-assembled conductive paste and may thus be applied to wearable devices, which are required to exhibit increased conductivity and durability of joints thereof, a minimized foreign-body sensation and an improved wearing sensation, and a method of manufacturing the same.

### 2. Description of the Related Art

As wearable electronic devices have recently become a paradigm of the times, thorough research into electronic textiles that combine the functions of electronic devices with textiles such as clothes is ongoing. Textiles are flexible and comfortable and thus make people feel less tired even when worn all day, and are thereby receiving attention as an ideal platform for wearable electronic devices.

However, electronic devices mounted on clothes or textiles have to be installed so as to enable the user's freedom of activity, and need to be made of washable and durable elements, which is under active study.

Conventional functional electronic textile products are configured such that electronic parts and wires that function electronically are invisibly packaged with textiles, or are connected to electronic parts using conductive yarns instead of using wires.

Conventional products in which wires and electronic parts are invisibly packaged have a foreign-body sensation due to the wires and electronic parts, and have no elasticity, which makes them less comfortable to wear. Moreover, in the case of conventional product processing for connecting electronic parts using conductive yarn, an additional process such as soldering, seam sealing, embroidering, sewing, etc. for connecting the conductive yarn and the electronic part is required during the manufacturing process. Here, since soldering is carried out at a high temperature, there is a risk of damage to the fabric and fire, and products manufactured using seam-sealing films have problems of low durability of joints thereof and poor contact resistance.

These conventional problems have complicated the processing of functional electronic textiles, ultimately making it difficult to enter the mass-production stage due to problems with productivity, durability, etc., and thus there are difficulties in expanding the functional electronic textile market.

### SUMMARY OF THE INVENTION

Accordingly, the present invention has been made keeping in mind the problems encountered in the related art, and an objective of the present invention is to provide a fiber composite laminate and a conductive fiber composite laminate, which include a self-assembled conductive paste and may thus be applied to wearable devices having increased conductivity and durability of joints thereof, a minimized foreign-body sensation and an improved wearing sensation.

Another objective of the present invention is to provide a method of manufacturing the fiber composite laminate and the conductive fiber composite laminate, in which productivity may be improved through simple processing and mass production is possible.

An aspect of the present invention provides a fiber composite laminate 10, configured to include a fiber-based circuit unit 100, including a fiber substrate 110 and a circuit electrode 120 positioned on the fiber substrate 110, a composite binder unit 200 positioned on the fiber-based circuit unit 100, and a connection unit 300, including a connection electrode 310 positioned on the composite binder unit 200 and a flexible substrate 320 positioned on the composite binder unit 200 and the connection electrode 310.

Also, the fiber-based circuit unit 100 may be adhered to the connection unit 300 by the composite binder unit 200.

Also, the composite binder unit 200 includes a binder portion 210 and a conductor portion 220, the binder portion 210 may be positioned between the fiber substrate 110 and the flexible substrate 320, and the conductor portion 220 may be positioned between the circuit electrode 120 and the connection electrode 310.

Also, the conductor portion 220 may include a conductor, and may electrically connect the circuit electrode 120 and the connection electrode 310 to each other.

Also, the conductor may include at least one selected from the group consisting of gallium, indium, tin, silver, bismuth, copper, zinc, antimony, nickel and alloys thereof. Furthermore, the conductor may include at least one selected from the group consisting of a eutectic gallium-indium alloy and a gallium-indium-tin alloy.

Also, the binder portion may include at least one selected from the group consisting of an acrylic resin, an epoxy resin, a phenoxy resin, a urethane resin, a polyester resin, a polyamide resin, a polyvinyl alcohol resin, a nitrile resin, a polyvinyl chloride resin and polyethylene.

Also, the acrylic resin may include at least one selected from the group consisting of bisphenol A diglycidyl ether diacrylate (BAGEDA), 1,4-butanediol diglycidyl ether diacrylate (BDGEDA), 2,2-bis[4-(2-hydroxy-3-methacryloxypropoxy)phenyl]propane (Bis-GMA), ethylene glycol dimethacrylate (EGDMA), triethylene glycol dimethacrylate (TEGDMA), ethoxylated bisphenol A dimethacrylate (Bis-EMA), urethane dimethacrylate (UDMA), dipentaerythritol pentaacrylate monophosphate (PENTA), 2-hydroxyethyl methacrylate (HEMA), polyalkenoic acid, biphenyl dimethacrylate (BPDM) and glycerol phosphate dimethacrylate (GPDM).

Also, the composite binder unit may include 10 to 1,000 parts by weight of the conductor portion based on 100 parts by weight of the binder portion.

Also, the composite binder unit may further include at least one selected from the group consisting of a thermal initiator and a curing agent.

Here, the thermal initiator may be an azo-based compound or a peroxide-based compound.

The thermal initiator may include at least one selected from the group consisting of azobisisobutyronitrile (AIBN), 2,2-azobis(2-methyl butyronitrile), dibenzoyl peroxide, tert-butylperoxy benzoate, di-tert-butyl peroxide, tert-butylperoxy-2-ethyl hexanoate, tert-butylperoxy acetate, cumyl hydroperoxide, dicumyl peroxide and tert-butyl hydroperoxide.

The amount of the thermal initiator may be 0.1 to 10 parts by weight based on 100 parts by weight of the binder portion.

Also, the curing agent may include at least one selected from the group consisting of dicyandiamide, a phenol novolac curing agent, imidazole, and an amine-based curing agent.

Also, the fiber substrate may include at least one polymer selected from the group consisting of polyamide, polyester, polyurethane, polyethylene, polyvinyl chloride, polyvinylidene chloride, polyfluoroethylene, a vinylon resin, polyvinyl alcohol, polyacrylonitrile, an acrylic resin, an epoxy resin and polypropylene.

Also, the circuit electrode may include a conductive yarn.

Also, the conductive yarn may include a fiber and a conductive layer applied on the fiber.

Also, the fiber may include at least one polymer selected from the group consisting of polyamide, polyester, polyurethane, polyethylene, polyvinyl chloride, polyvinylidene chloride, polyfluoroethylene, vinylon, polyvinyl alcohol, polyacrylonitrile, acryl and polypropylene.

Also, the conductive layer may include at least one selected from the group consisting of silver, gold, aluminum, copper, platinum, palladium, tin, graphene and carbon nanotubes (CNT).

Also, the flexible substrate may include at least one selected from the group consisting of polyimide, polyamide, polyester, polytetrafluoroethylene, polyethylene, polypropylene and polyethylene terephthalate.

Also, the connection electrode may include at least one selected from the group consisting of silver, gold, aluminum, copper, platinum, palladium, tin, graphene and carbon nanotubes (CNT).

Also, the connection unit may serve to electrically connect an electronic device.

Another aspect of the present invention provides an electronic part 20, configured to include a fiber-based circuit unit 100, including a fiber substrate 110 and a circuit electrode 120 positioned on the fiber substrate 110, a composite binder unit 200 positioned on the fiber-based circuit unit 100, a connection unit 300, including a connection electrode 310 positioned on the composite binder unit 200 and a flexible substrate 320 positioned on the composite binder unit 200 and the connection electrode 310, and an electronic device electrically connected to the connection unit.

Still another aspect of the present invention provides a method of manufacturing a fiber composite laminate, the method including (a) providing a fiber-based circuit unit 100 including a fiber substrate 110 and a circuit electrode 120 positioned on the fiber substrate 110, (b) providing a connection unit 300 including a flexible substrate 320 and a connection electrode 310 positioned on the flexible substrate 320, (c) manufacturing a fiber-based circuit unit/composite binder/connection unit by positioning a composite binder including a binder and a conductor between the fiber-based circuit unit 100 and the connection unit 300, and (d) melting and self-assembling the composite binder of the fiber-based circuit unit 100/composite binder/connection unit 300, whereby a conductor portion 220 including the conductor is positioned between the circuit electrode 120 and the connection electrode 310 and a binder portion 210 including the binder is positioned between the fiber substrate 110 and the flexible substrate 320.

According to the present invention, a fiber composite laminate includes a self-assembled conductive paste and can thus be applied to wearable devices having increased conductivity and durability of joints thereof, a minimized foreign-body sensation and an improved wearing sensation.

Also, according to the present invention, a method of manufacturing the fiber composite laminate is capable of improving productivity through simple processing and enables mass production.

### BRIEF DESCRIPTION OF DRAWINGS

Since these drawings are for reference in describing exemplary embodiments of the present invention, the technical spirit of the present invention should not be construed as being limited to the accompanying drawings, in which:

FIG. 1 schematically shows the structure of a fiber composite laminate according to the present invention;

FIG. 2 schematically shows a process of manufacturing a fiber composite laminate according to the present invention;

FIG. 3 schematically shows a process of manufacturing a fiber composite laminate due to the melting of a composite binder during the manufacture of the fiber composite laminate according to the present invention; and

FIG. 4 is a real image of the fiber composite laminate manufactured in Example 1.

### DESCRIPTION OF SPECIFIC EMBODIMENTS

Hereinafter, exemplary embodiments of the present invention are described in detail with reference to the appended drawings so as to be easily performed by a person having ordinary skill in the art.

However, the following description does not limit the present invention to specific embodiments, and moreover, descriptions of known techniques, even if they are pertinent to the present invention, are considered unnecessary and may be omitted insofar as they would make the characteristics of the invention unclear.

The terms herein are used to explain specific embodiments, and are not intended to limit the present invention. Unless otherwise stated, a singular expression includes a plural expression. In this application, the terms “include” or “have” are used to designate the presence of features, numbers, steps, operations, elements, parts, or combinations thereof described in the specification, and should be understood as not excluding the presence or additional possible presence of one or more different features, numbers, steps, operations, elements, parts, or combinations thereof.

As used herein, the terms “first”, “second”, etc. may be used to describe various elements, but these elements are not to be limited by these terms. These terms are only used to distinguish one element from another. For example, a first element may be termed a second element, and similarly, a second element may be termed a first element, without departing from the scope of the present invention.

Further, it will be understood that when an element is referred to as being “formed” or “stacked” on another element, it can be formed or stacked so as to be directly attached to all surfaces or to one surface of the other element, or intervening elements may be present therebetween.

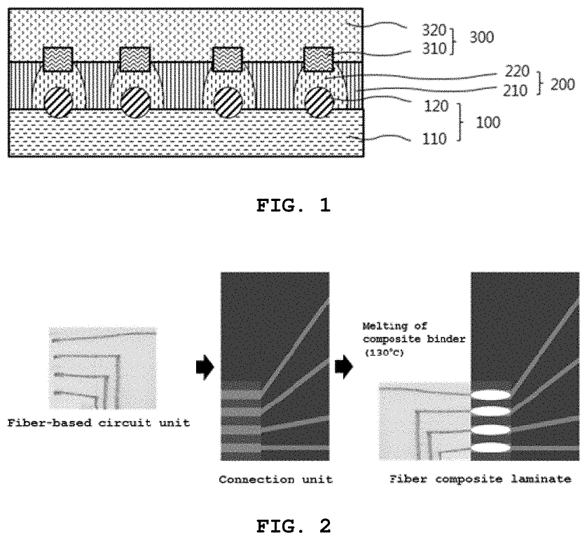

FIG. 1 schematically shows the structure of a fiber composite laminate according to the present invention. Hereinafter, a detailed description will be given of a fiber composite laminate according to the present invention with reference to FIG. 1, which is merely set forth to illustrate the present invention but is not to be construed as limiting the present invention, and is defined by the scope of the accompanying claims.

The present invention pertains to a fiber composite laminate 10, configured to include a fiber-based circuit unit 100, including a fiber substrate 110 and a circuit electrode 120 positioned on the fiber substrate 110, a composite binder unit 200 positioned on the fiber-based circuit unit 100, and a connection unit 300, including a connection electrode 310 positioned on the composite binder unit 200 and a flexible substrate 320 positioned on the composite binder unit 200 and the connection electrode 310.

Also, the fiber-based circuit unit 100 may be adhered to the connection unit 300 by the composite binder unit 200. Also, the composite binder unit 200 includes a binder portion 210 and a conductor portion 220, the binder portion 210 may be positioned between the fiber substrate 110 and the flexible substrate 320, and the conductor portion 220 may be positioned between the circuit electrode 120 and the connection electrode 310.

Also, the conductor portion 220 includes a conductor and may function to electrically connect the circuit electrode 120 and the connection electrode 310 to each other.

Also, the conductor may include at least one selected from the group consisting of gallium, indium, tin, silver, bismuth, copper, zinc, antimony, nickel and alloys thereof, preferably includes at least one selected from the group consisting of gallium, indium, tin and alloys thereof, and more preferably includes at least one selected from the group consisting of a eutectic gallium-indium alloy and a gallium-indium-tin alloy.

Also, the binder portion may include at least one selected from the group consisting of an acrylic resin, an epoxy resin, a phenoxy resin, a urethane resin, a polyester resin, a polyamide resin, a polyvinyl alcohol resin, a nitrile resin, a polyvinyl chloride resin and polyethylene, and preferably includes at least one selected from the group consisting of an acrylic resin and a phenoxy resin.

Also, the acrylic resin may include at least one selected from the group consisting of bisphenol A diglycidyl ether diacrylate (BAGEDA), 1,4-butanediol diglycidyl ether diacrylate (BDGEDA), 2,2-bis[4-(2-hydroxy-3-methacryloxypropoxy)phenyl]propane (Bis-GMA), ethylene glycol dimethacrylate (EGDMA), triethylene glycol dimethacrylate (TEGDMA), ethoxylated bisphenol A dimethacrylate (Bis-EMA), urethane dimethacrylate (UDMA), dipentaerythritol pentaacrylate monophosphate (PENTA), 2-hydroxyethyl methacrylate (HEMA), polyalkenoic acid, biphenyl dimethacrylate (BPDM) and glycerol phosphate dimethacrylate (GPDM), and preferably includes bisphenol A diglycidyl ether diacrylate.

Also, the composite binder unit may include the conductor portion in an amount of 10 to 1,000 parts by weight, preferably 100 to 900 parts by weight, more preferably 300 to 800 parts by weight, and much more preferably 450 to 700 parts by weight, based on 100 parts by weight of the binder portion. If the amount of the conductor is less than 10 parts by weight, self-assembly may become problematic. On the other hand, if the amount thereof exceeds 1,000 parts by weight, adhesion may become problematic, and residual particles that are not self-assembled may be left behind.

Also, the composite binder unit may further include at least one selected from the group consisting of a thermal initiator and a curing agent. Useful in the present invention, the thermal initiator may be an azo-based compound or a peroxide-based compound, examples of which may include azobisisobutyronitrile (AIBN), 2,2-azobis(2-methyl butyronitrile), dibenzoyl peroxide, tert-butylperoxy benzoate, di-tert-butyl peroxide, tert-butylperoxy-2-ethyl hexanoate, tert-butylperoxy acetate, cumyl hydroperoxide, dicumyl peroxide, tert-butyl hydroperoxide, and the like.

The amount of the thermal initiator may be 0.1 to 10 parts by weight based on 100 parts by weight of the resin. If the amount thereof is less than 0.1 parts by weight, it is difficult to carry out a sufficient radical initiation reaction. On the other hand, if the amount thereof exceeds 10 parts by weight, resin degradation may occur due to the unreacted initiator, undesirably deteriorating the properties thereof.

Useful in the present invention, the curing agent may include dicyandiamide, a phenol novolac curing agent, imidazole, or an amine-based curing agent.

Also, the fiber substrate may include at least one polymer selected from the group consisting of polyamide, polyester, polyurethane, polyethylene, polyvinyl chloride, polyvinylidene chloride, polyfluoroethylene, a vinylon resin, polyvinyl alcohol, polyacrylonitrile, an acrylic resin, an epoxy resin and polypropylene.

Also, the circuit electrode may include a conductive yarn.

Also, the conductive yarn may include a fiber and a conductive layer applied on the fiber.

Also, the fiber may include at least one polymer selected from the group consisting of polyamide, polyester, polyurethane, polyethylene, polyvinyl chloride, polyvinylidene chloride, polyfluoroethylene, vinylon, polyvinyl alcohol, polyacrylonitrile, acryl and polypropylene, and preferably includes polyamide.

Also, the conductive layer may include at least one selected from the group consisting of silver, gold, aluminum, copper, platinum, palladium, tin, graphene and carbon nanotubes (CNT), and preferably includes silver.

Also, the flexible substrate may include at least one selected from the group consisting of polyimide, polyamide, polyester, polytetrafluoroethylene, polyethylene, polypropylene and polyethylene terephthalate.

Also, the connection electrode may include at least one selected from the group consisting of silver, gold, aluminum, copper, platinum, palladium, tin, graphene and carbon nanotubes (CNT).

Also, the connection unit may function to electrically connect an electronic device.

In addition, the present invention pertains to an electronic part 20, configured to include a fiber-based circuit unit 100, including a fiber substrate 110 and a circuit electrode 120 positioned on the fiber substrate 110, a composite binder unit 200 positioned on the fiber-based circuit unit 100, a connection unit 300, including a connection electrode 310 positioned on the composite binder unit 200 and a flexible substrate 320 positioned on the composite binder unit 200 and the connection electrode 310, and an electronic device electrically connected to the connection unit.

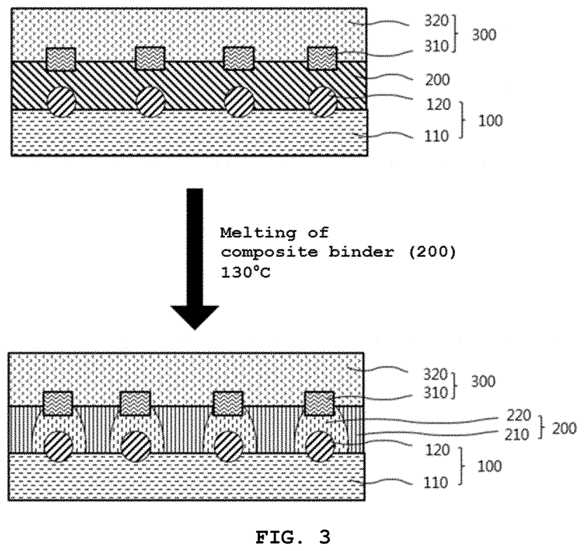

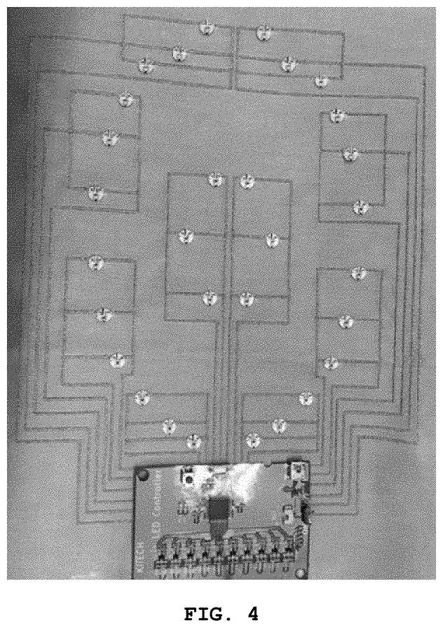

FIG. 2 schematically shows the process of manufacturing the fiber composite laminate according to the present invention, and FIG. 3 schematically shows the process of manufacturing the fiber composite laminate due to the melting of the composite binder during the manufacture of the fiber composite laminate according to the present invention. Below is a description of the method of manufacturing the fiber composite laminate according to the present invention with reference to FIGS. 2 and 3.

Specifically, a fiber-based circuit unit 100 including a fiber substrate 110 and a circuit electrode 120 positioned on the fiber substrate 110 is provided (step a).

Next, a connection unit 300 including a flexible substrate 320 and a connection electrode 310 positioned on the flexible substrate 320 is provided (step b).

Next, a fiber-based circuit unit/composite binder/connection unit is manufactured by positioning a composite binder including a binder and a conductor between the fiber-based circuit unit 100 and the connection unit 300 (step c).

Finally, the composite binder of the fiber-based circuit unit 100/composite binder/connection unit 300 is melted and self-assembled, whereby a conductor portion 220 including the conductor is positioned between the circuit electrode 120 and the connection electrode 310 and a binder portion 210 including the binder is positioned between the fiber substrate 110 and the flexible substrate 320 (step d).

The fiber-based circuit unit in step a may be manufactured by forming the circuit electrode using the conductive yarn on the fiber substrate through at least one process selected from among embroidering, knitting, weaving and printing using conductive ink.

### EXAMPLES

A better understanding of the present invention will be given through the following examples, which are merely set forth to illustrate the present invention but are not to be construed as limiting the scope of the present invention.

Composite Binder (Self-Assembled Conductive Paste)

### Preparation Example 1

A composite binder was manufactured by mixing 100 parts by weight of bisphenol A diglycidyl ether diacrylate (BAGEDA) as a binder, 300 parts by weight of a eutectic gallium-indium alloy as a conductor, 165 parts by weight of ethyl carbitol acetate as a solvent, and 11 parts by weight of azobisisobutyronitrile (AIBN) as an initiator. The eutectic gallium-indium alloy was composed of 75.5 wt % gallium and 24.5 wt % indium.

### Preparation Examples 2 to 7

Respective composite binders of Preparation Examples 2 to 7 were manufactured in the same manner as in Preparation Example 1 using components in the amounts shown in Table 1 below.

### Preparation Example 8

A composite binder was manufactured in the same manner as in Preparation Example 1, with the exception that 700 parts by weight of a eutectic gallium-indium-tin alloy was used in lieu of 300 parts by weight of the eutectic gallium-indium alloy. The eutectic gallium-indium-tin alloy was composed of 68.5 wt % gallium, 21.5 wt % indium, and 10 wt % tin.

### Preparation Example 9

A composite binder was manufactured in the same manner as in Preparation Example 1, with the exception that the eutectic gallium-indium alloy was used in an amount of 700 parts by weight, rather than 300 parts by weight, a phenoxy resin was used in lieu of bisphenol A diglycidyl ether diacrylate, and dicyandiamide was used in lieu of azobisisobutyronitrile (AIBN).

### Preparation Example 10

A composite binder was manufactured in the same manner as in Preparation Example 1, with the exception that the eutectic gallium-indium alloy was used in an amount of 700 parts by weight, rather than 300 parts by weight, a phenoxy resin was used in lieu of bisphenol A diglycidyl ether diacrylate, and 5.5 parts by weight of azobisisobutyronitrile (AIBN) and 5.5 parts by weight of dicyandiamide were used in lieu of 11 parts by weight of azobisisobutyronitrile (AIBN).

The components and amounts (parts by weight) of the composite binders of Preparation Examples 1 to 10 are summarized in Table 1 below.

TABLE 1

| | Binder | | Conductor | | | | |
|---|---|---|---|---|---|---|---|
| | | Amount | | Amount | AIBN | Dicyanamide | Solvent |
| | | (parts by | | (parts by | (parts by | (parts by | (parts by |
| No. | Kind | weight) | Kind | weight) | weight) | weight) | weight) |
| Preparation | BAGEDA | 100 | Ga—In | 300 | 11 | 0 | 165 |
| Example 1 | | | | | | | |
| Preparation | BAGEDA | 100 | Ga—In | 400 | 11 | 0 | 206 |
| Example 2 | | | | | | | |
| Preparation | BAGEDA | 100 | Ga—In | 500 | 11 | 0 | 248 |
| Example 3 | | | | | | | |
| Preparation | BAGEDA | 100 | Ga—In | 700 | 11 | 0 | 330 |
| Example 4 | | | | | | | |
| Preparation | BAGEDA | 100 | Ga—In | 900 | 11 | 0 | 413 |
| Example 5 | | | | | | | |
| Preparation | BAGEDA | 100 | Ga—In | 1,000 | 11 | 0 | 454 |
| Example 6 | | | | | | | |
| Preparation | BAGEDA | 100 | Ga—In | 1,100 | 11 | 0 | 495 |
| Example 7 | | | | | | | |
| Preparation | BAGEDA | 100 | Ga—In—Sn | 700 | 11 | 0 | 330 |
| Example 8 | | | | | | | |
| Preparation | Phenoxy | 100 | Ga—In | 700 | 0 | 11 | 330 |
| Example 9 | resin | | | | | | |
| Preparation | Phenoxy | 100 | Ga—In | 700 | 5.5 | 5.5 | 330 |
| Example 10 | resin | | | | | | |

Fiber Composite Laminate and Electronic Part

Manufacture of Fiber Composite Laminate and Electronic Part Depending on Components And Amounts of Composite Binder (Examples 1 to 7)

### Example 1

A communication module, a signal-processing module, a driving circuit, an amplification circuit, and the like, which are functional electronic devices that are difficult to replace with fiber circuits, were mounted through soldering on an F-PCB (Flexible PCB) using an imide film.

Furthermore, a circuit for LED parallel connection and contact with a driving electrode was embroidered on a polyester nonwoven fabric using a conductive yarn (Silver-tech 120, available from Amann) having a silver content of 41 wt % composed of silver (Ag)-coated nylon yarn (Ag-coated yarn).

The composite binder (self-assembled conductive paste) of Preparation Example 1 was applied on the electrode region of the F-PCB (Flexible PCB).

The electrode region of the F-PCB (Flexible PCB) coated with the self-assembled conductive paste was aligned with the electrode region of the fiber-based circuit, pressurized, and self-assembled and cured in a drying oven at 140° C. for 20 min, thereby manufacturing a fiber composite laminate and an electronic part including the same.

FIG. 3 shows the electronic part including an LED including the fiber composite laminate of Example 1.

### Example 2

A fiber composite laminate and an electronic part including the same were manufactured in the same manner as in Example 1, with the exception that the composite binder of Preparation Example 2 was used in lieu of the composite binder of Preparation Example 1, and self-assembly and curing in a drying oven at 130° C. for 20 min were performed in lieu of self-assembly and curing in a drying oven at 140° C. for 20 min.

Example 3

A fiber composite laminate and an electronic part including the same were manufactured in the same manner as in Example 1, with the exception that the composite binder of Preparation Example 3 was used in lieu of the composite binder of Preparation Example 1, and self-assembly and curing in a drying oven at 130° C. for 10 min were performed in lieu of self-assembly and curing in a drying oven at 140° C. for 20 min.

### Example 4

A fiber composite laminate and an electronic part including the same were manufactured in the same manner as in Example 1, with the exception that the composite binder of Preparation Example 4 was used in lieu of the composite binder of Preparation Example 1, and self-assembly and curing in a drying oven at 130° C. for 10 min were performed in lieu of self-assembly and curing in a drying oven at 140° C. for 20 min.

### Example 5

A fiber composite laminate and an electronic part including the same were manufactured in the same manner as in Example 1, with the exception that the composite binder of Preparation Example 5 was used in lieu of the composite binder of Preparation Example 1, and self-assembly and curing in a drying oven at 130° C. for 10 min were performed in lieu of self-assembly and curing in a drying oven at 140° C. for 20 min.

### Example 6

A fiber composite laminate and an electronic part including the same were manufactured in the same manner as in Example 1, with the exception that the composite binder of Preparation Example 6 was used in lieu of the composite binder of Preparation Example 1.

### Example 7

A fiber composite laminate and an electronic part including the same were manufactured in the same manner as in Example 1, with the exception that the composite binder of Preparation Example 7 was used in lieu of the composite binder of Preparation Example 1.

### Example 8

A fiber composite laminate and an electronic part including the same were manufactured in the same manner as in Example 1, with the exception that the composite binder of Preparation Example 8 was used in lieu of the composite binder of Preparation Example 1, and self-assembly and curing in a drying oven at 130° C. for 10 min were performed in lieu of self-assembly and curing in a drying oven at 140° C. for 20 min.

### Example 9

A fiber composite laminate and an electronic part including the same were manufactured in the same manner as in Example 1, with the exception that the composite binder of Preparation Example 9 was used in lieu of the composite binder of Preparation Example 1, and self-assembly and curing in a drying oven at 130° C. for 10 min were performed in lieu of self-assembly and curing in a drying oven at 140° C. for 20 min.

### Example 10

A fiber composite laminate and an electronic part including the same were manufactured in the same manner as in Example 1, with the exception that the composite binder of Preparation Example 10 was used in lieu of the composite binder of Preparation Example 1, and self-assembly and curing in a drying oven at 130° C. for 10 min were performed in lieu of self-assembly and curing in a drying oven at 140° C. for 20 min.

### Example 11

A fiber composite laminate and an electronic part including the same were manufactured in the same manner as in Example 1, with the exception that a conductive yarn (70D/24F, available from Qingdao) having a silver content of 38 wt % was used in lieu of the conductive yarn having a silver content of 41 wt %, the composite binder of Preparation Example 4 was used in lieu of the composite binder of Preparation Example 1, and self-assembly and curing in a drying oven at 130° C. for 10 min were performed in lieu of self-assembly and curing in a drying oven at 140° C. for 20 min.

### Example 12

A fiber composite laminate and an electronic part including the same were manufactured in the same manner as in Example 1, with the exception that a conductive yarn (234/f34_PA/Ag, available from Imbut) having a silver content of 87 wt % was used in lieu of the conductive yarn having a silver content of 41 wt %, the composite binder of Preparation Example 4 was used in lieu of the composite binder of Preparation Example 1, and self-assembly and curing in a drying oven at 130° C. for 10 min were performed in lieu of self-assembly and curing in a drying oven at 140° C. for 20 min.

The components of the fiber composite laminates and the electronic parts including the same according to Examples 1 to 12, the temperature and time for self-assembly, adhesion and contact resistance are summarized in Table 2 below.

TABLE 2

| | | Conductive yarn | | Self-assembly | |
|---|---|---|---|---|---|
| | Composite | | Ag content | Temp. | Time |
| No. | binder | Kind | (wt %) | (° C.) | (min) |
| Example 1 | Preparation | Ag-coated | 41 | 140 | 20 |
| | Example 1 | yarn | | | |
| Example 2 | Preparation | Ag-coated | 41 | 130 | 20 |
| | Example 2 | yarn | | | |
| Example 3 | Preparation | Ag-coated | 41 | 130 | 10 |
| | Example 3 | yarn | | | |
| Example 4 | Preparation | Ag-coated | 41 | 130 | 10 |
| | Example 4 | yarn | | | |
| Example 5 | Preparation | Ag-coated | 41 | 130 | 10 |
| | Example 5 | yarn | | | |
| Example 6 | Preparation | Ag-coated | 41 | 140 | 20 |
| | Example 6 | yarn | | | |
| Example 7 | Preparation | Ag-coated | 41 | 140 | 20 |
| | Example 7 | yarn | | | |
| Example 8 | Preparation | Ag-coated | 41 | 130 | 10 |
| | Example 8 | yarn | | | |
| Example 9 | Preparation | Ag-coated | 41 | 130 | 10 |
| | Example 9 | yarn | | | |
| Example 10 | Preparation | Ag-coated | 41 | 130 | 10 |
| | Example 10 | yarn | | | |
| Example 11 | Preparation | Ag-coated | 38 | 130 | 10 |
| | Example 4 | yarn | | | |
| Example 12 | Preparation | Ag-coated | 87 | 130 | 10 |
| | Example 4 | yarn | | | |

### TEST EXAMPLES

### Test Example 1

### Evaluation of Self-Assembling Performance Depending on Amount of Composite Binder Composition

The conditions for self-assembly of the composite binders between the fiber substrates and the flexible substrates of Examples 1 to 7 are shown in Table 3 below.

TABLE 3

| | | | Conditions for | |
|---|---|---|---|---|
| | | | self-assembly | |
| | Composite | Conductor amount | Temp. | Time |
| No. | binder | (parts by weight) | (° C.) | (min) |
| Example 1 | Preparation | 300 | 140 | 20 or more |
| | Example 1 | | | |
| Example 2 | Preparation | 400 | 130 | 20 or more |
| | Example 2 | | | |
| Example 3 | Preparation | 500 | 130 | 10 or more |
| | Example 3 | | | |
| Example 4 | Preparation | 700 | 130 | 10 or more |
| | Example 4 | | | |
| Example 5 | Preparation | 900 | 130 | 10 or more |
| | Example 5 | | | |
| Example 6 | Preparation | 1,000 | 140 | 20 or more |
| | Example 6 | | | |
| Example 7 | Preparation | 1,100 | 140 | 20 or more |
| | Example 7 | | | |

As is apparent from Table 3, the composite binders of Preparation Examples 3 and 4 were self-assembled at a low temperature in a short time and thus exhibited the greatest self-assembling performance, the composite binders of Preparation Examples 2 and 5 exhibited good self-assembling performance, and the composite binders of Preparation Examples 1, 6 and 7 exhibited fair self-assembling performance. Therefore, it can be confirmed that the self-assembling performance of the composite binders was increased and then decreased with an increase in the amount of the conductor.

### Test Example 2

### Evaluation of Adhesion and Contact Resistance of Composite Binder Composition

The adhesion and contact resistance of Example 4 and Examples 8 to 12 were measured. The results thereof are shown in Table 4 below.

Adhesion was determined using a UTM (Universal Testing Machine) in a manner in which the fiber textile portion and the F-PCB, which were adhered through self-assembly, were clamped by the fixing clamps of a tension tester and strength applied upon peeling was measured at a tension tester speed of 20 mm/min.

Contact resistance was determined by measuring the voltage at both ends of a connector at a test current of 1 mA using a Keithley SourceMeter 2400.

TABLE 4

| | | | Conductive yarn | | AIBN/Amide | | | |
|---|---|---|---|---|---|---|---|---|
| | | | | Ag | AIBN | Amide | | Contact |
| | Composite binder | | | content | (parts by | (parts by | Adhesion | resistance |
| No. | Binder | Conductor | Kind | (wt %) | weight) | weight) | (kgf/cm²) | (Ω/cm) |
| Example 4 | BAGEDA | Ga—In | Ag-coated yarn | 41 | 11 | 0 | 1.8 | 1.0 |
| Example 8 | BAGEDA | Ga—In—Sn | Ag-coated yarn | 41 | 11 | 0 | 1.8 | 1.5 |
| Example 9 | Phenoxy | Ga—In | Ag-coated yarn | 41 | 0 | 11 | 2.5 | 0.8 |
| | resin | | | | | | | |
| Example 10 | Phenoxy | Ga—In | Ag-coated yarn | 41 | 5.5 | 5.5 | 2.3 | 0.8 |
| | resin | | | | | | | |
| Example 11 | BAGEDA | Ga—In | Ag-coated yarn | 38 | 11 | 0 | 1.8 | 1.0 |
| Example 12 | BAGEDA | Ga—In | Ag-coated yarn | 87 | 11 | 0 | 1.3 | 0.5 |

As is apparent from Table 4, the adhesion and contact resistance depending on the kind of conductor under the same conditions in Example 4 and Example 8 were confirmed. When using the eutectic gallium-indium-tin alloy as the conductor (Example 8), consistent adhesion and increased contact resistance resulted.

The contact resistance was lower in Example 9 and Example 10 using the phenoxy resin as the binder than in Example 4 using the bisphenol A diglycidyl ether binder.

Moreover, when the phenoxy resin was used as the binder, the adhesion was higher in Example 9 using dicyandiamide than in Example 10 using AIBN and dicyandiamide at a weight ratio of 50:50.

Furthermore, the adhesion and contact resistance were consistent when the silver content of the conductive yarn was 41% and 38%, but when the silver content was increased to 87%, adhesion was decreased to 1.3 kgf/cm² and contact resistance was decreased to 0.5 Q/cm.

The scope of the invention is represented by the claims below rather than the aforementioned detailed description, and all changes or modified forms that are capable of being derived from the meaning, range, and equivalent concepts of the appended claims should be construed as being included in the scope of the present invention.

What is claimed is:

1. A fiber composite laminate, comprising:
a fiber-based circuit unit including a fiber substrate and a circuit electrode positioned on the fiber substrate;
a composite binder unit positioned on the fiber-based circuit unit; and
a connection unit including a connection electrode positioned on the composite binder unit and a flexible substrate positioned on the composite binder unit and the connection electrode.

2. The fiber composite laminate of claim 1, wherein the fiber-based circuit unit is adhered to the connection unit by the composite binder unit.

3. The fiber composite laminate of claim 1, wherein the composite binder unit includes a binder portion and a conductor portion,
the binder portion is positioned between the fiber substrate and the flexible substrate, and
the conductor portion is positioned between the circuit electrode and the connection electrode.

4. The fiber composite laminate of claim 3, wherein the conductor portion includes a conductor and serves to electrically connect the circuit electrode and the connection electrode.

5. The fiber composite laminate of claim 4, wherein the conductor includes at least one selected from the group consisting of gallium, indium, tin, silver, bismuth, copper, zinc, antimony, nickel and alloys thereof.

6. The fiber composite laminate of claim 5, wherein the conductor includes at least one selected from the group consisting of a eutectic gallium-indium alloy and a gallium-indium-tin alloy.

7. The fiber composite laminate of claim 3, wherein the binder portion includes at least one selected from the group consisting of an acrylic resin, an epoxy resin, a phenoxy resin, a urethane resin, a polyester resin, a polyamide resin, a polyvinyl alcohol resin, a nitrile resin, a polyvinyl chloride resin and polyethylene.

8. The fiber composite laminate of claim 7, wherein the acrylic resin includes at least one selected from the group consisting of bisphenol A diglycidyl ether diacrylate (BAGEDA), 1,4-butanediol diglycidyl ether diacrylate (BDGEDA), 2,2-bis[4-(2-hydroxy-3-methacryloxypropoxy)phenyl]propane (Bis-GMA), ethylene glycol dimethacrylate (EGDMA), triethylene glycol dimethacrylate (TEGDMA), ethoxylated bisphenol A dimethacrylate (Bis-EMA), urethane dimethacrylate (UDMA), dipentaerythritol pentaacrylate monophosphate (PENTA), 2-hydroxyethyl methacrylate (HEMA), polyalkenoic acid, biphenyl dimethacrylate (BPDM) and glycerol phosphate dimethacrylate (GPDM).

9. The fiber composite laminate of claim 3, wherein the composite binder unit includes 10 to 1,000 parts by weight of the conductor portion based on 100 parts by weight of the binder portion.

10. The fiber composite laminate of claim 1, wherein the composite binder unit further includes at least one selected from the group consisting of a thermal initiator and a curing agent.

11. The fiber composite laminate of claim 1, wherein the fiber substrate includes at least one polymer selected from the group consisting of polyamide, polyester, polyurethane, polyethylene, polyvinyl chloride, polyvinylidene chloride, polyfluoroethylene, a vinylon resin, polyvinyl alcohol, polyacrylonitrile, an acrylic resin, an epoxy resin and polypropylene.

12. The fiber composite laminate of claim 1, wherein the circuit electrode includes a conductive yarn.

13. The fiber composite laminate of claim 12, wherein the conductive yarn includes a fiber and a conductive layer applied on the fiber.

14. The fiber composite laminate of claim 13, wherein the fiber includes at least one polymer selected from the group consisting of polyamide, polyester, polyurethane, polyethylene, polyvinyl chloride, polyvinylidene chloride, polyfluoroethylene, vinylon, polyvinyl alcohol, polyacrylonitrile, acryl and polypropylene.

15. The fiber composite laminate of claim 13, wherein the conductive layer includes at least one selected from the group consisting of silver, gold, aluminum, copper, platinum, palladium, tin, graphene and carbon nanotubes (CNT).

16. The fiber composite laminate of claim 1, wherein the flexible substrate includes at least one selected from the group consisting of polyimide, polyamide, polyester, polytetrafluoroethylene, polyethylene, polypropylene and polyethylene terephthalate.

17. The fiber composite laminate of claim 1, wherein the connection electrode includes at least one selected from the group consisting of silver, gold, aluminum, copper, platinum, palladium, tin, graphene and carbon nanotubes (CNT).

18. The fiber composite laminate of claim 1, wherein the connection unit serves to electrically connect an electronic device.

19. An electronic part, comprising:
a fiber-based circuit unit including a fiber substrate and a circuit electrode positioned on the fiber substrate;
a composite binder unit positioned on the fiber-based circuit unit;
a connection unit including a connection electrode positioned on the composite binder unit and a flexible substrate positioned on the composite binder unit and the connection electrode; and
an electronic device electrically connected to the connection unit.

20. A method of manufacturing a fiber composite laminate, the method comprising:
(a) providing a fiber-based circuit unit including a fiber substrate and a circuit electrode positioned on the fiber substrate;
(b) providing a connection unit including a flexible substrate and a connection electrode positioned on the flexible substrate;
(c) manufacturing a fiber-based circuit unit/composite binder/connection unit by positioning a composite binder including a binder and a conductor between the fiber-based circuit unit and the connection unit; and
(d) melting and self-assembling the composite binder of the fiber-based circuit unit/composite binder/connection unit, whereby a conductor portion including the conductor is positioned between the circuit electrode and the connection electrode and a binder portion including the binder is positioned between the fiber substrate and the flexible substrate.
